(19) United States
(12) Patent Application Publication
(10) Pub. No.: US 2017/0170103 A1
(43) Pub. Date: Jun. 15, 2017

(54) ELECTRONIC DEVICE AND MANUFACTURING METHOD THEREFOR

(71) Applicant: Nexperia B.V., Eindhoven (NL)

(72) Inventors: SHUN TIK YEUNG, Kwai Chung (HK); Pompeo V. UMALI, Kwai Chung (HK); On Lok CHAU, Kwai Chung (HK); Chi Ho LEUNG, Kwun Tong (HK); Kan Wae LAM, Kwai Chung (HK)

(21) Appl. No.: 15/368,653

(22) Filed: Dec. 4, 2016

(30) Foreign Application Priority Data
Dec. 11, 2015 (CN) 201510919622.9

(51) Int. Cl. H01L 23/495; H01L 21/48; H01L 21/56; H01L 23/31

(52) U.S. Cl. CPC H01L 23/49572; H01L 23/3114; H01L 21/4825; H01L 21/565; H01L 21/568

(57) ABSTRACT

An electronic device includes a conductive layer, a device die, and a connecting member. The conductive layer is formed by coating a conductive material on a substrate. The device die and the connecting member are disposed on the conductive layer and spaced from each other. The device die includes a first connection point on one side that is in contact with and electrically connected to the conductive layer, and a second connection point on another side thereof. The connecting member includes a third connection point on a side thereof electrically connected to and in contact with the conductive layer, and a fourth connection point on another side thereof. The second and fourth connection points are configured to provide external connections of the electronic device.

### BACKGROUND

The present invention relates to an electronic device and a method for manufacturing the same, and, more particularly, to an electronic device without a lead frame and a method for manufacturing a leadframe-less electronic device.

Electronic devices typically comprise a device die bonded to a lead frame using packaging techniques. In packaging, a device die formed in wafer fabrication is connected to the lead frame, and the device die and the lead frame are covered with molding material to form a final electronic device having a fixed structure. Connection parts of the lead frame and corresponding contacts of the device die are connected together with wires by wire bonding or other bonding techniques and are exposed to the outside through the corresponding part of the lead frame.

In the general manufacture of electronic devices, the lead frame configuration generally takes a lot of time, manpower and so on, and is an important node in the manufacturing cost of electronic devices.

It would be advantageous to provide an electronic device that saves cost and process time, and a method for manufacturing the electronic device.

### SUMMARY

This summary is provided to introduce a selection of concepts in a simplified form that are further described below in the Detailed Description. This summary is not intended to identify key or essential features of the claimed subject matter, nor is it intended to be used to limit the scope of the claimed subject matter.

An electronic device includes a conductive layer, a device die, and a connecting member. The conductive layer is formed by coating a conductive material on a substrate. The device die and the connecting member are disposed on the conductive layer and spaced from each other. The device die includes a first connection point on a side thereof that is in contact with and electrically connected to the conductive layer, and a second connection point on another side thereof. The connecting member includes a third connection point on one side thereof that is electrically connected to and in contact with the conductive layer, and a fourth connection point on another side of the connecting member. The second and fourth connection points are configured to provide external connections of the electronic device.

A method for manufacturing an electronic device includes: applying conductive material on a substrate to form a conductive layer; and arranging a device die and a connecting member on the conductive layer to be spaced from each other. The device die and the connecting member respectively have internal connection points on a side thereof contacting the conductive layer, and external connection points on another side thereof different from the side contacting the conductive layer. The method further includes ncapsulating the conductive layer, the device die, and the connecting member, and exposing the external connection points of the device die and the connecting member; and removing the substrate.

In embodiments of the present invention, the conductive layer is formed by applying conductive material on a substrate. Accordingly, during the manufacture of the electronic device, neither the use of a lead frame nor a step of wire bonding are necessary. The electronic device can be manufactured by applying the conductive layer, mounting the device die, and mounting the connecting member. The manufacturing cost and the processing time of the electronic device are reduced because a lead frame is not required.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments. The drawings are for facilitating an understanding of the invention and thus are not necessarily drawn to scale. Advantages of the subject matter claimed will become apparent to those skilled in the art upon reading this description in conjunction with the accompanying drawings, in which like reference numerals have been used to designate like elements, and in which:

FIGS. 1A and 1B are X-ray perspective views of an electronic device in accordance with an embodiment of the present invention;

FIG. 2 is a flow chart of a method for manufacturing an electronic device in accordance with an embodiment of the present invention;

FIGS. 3A-3I are cross-sectional side views illustrating resulting structures during the steps of the method for manufacturing an electronic device of FIG. 2;

FIG. 4 is a flow chart of a method for manufacturing an electronic device in accordance with another embodiment of the present invention;

FIGS. 5A-5J are cross-sectional side views of resulting structures during steps of the method for manufacturing an electronic device of FIG. 4; and

FIGS. 6A and 6B are perspective views of electronic device in accordance with another embodiment of the present invention.

### DETAILED DESCRIPTION

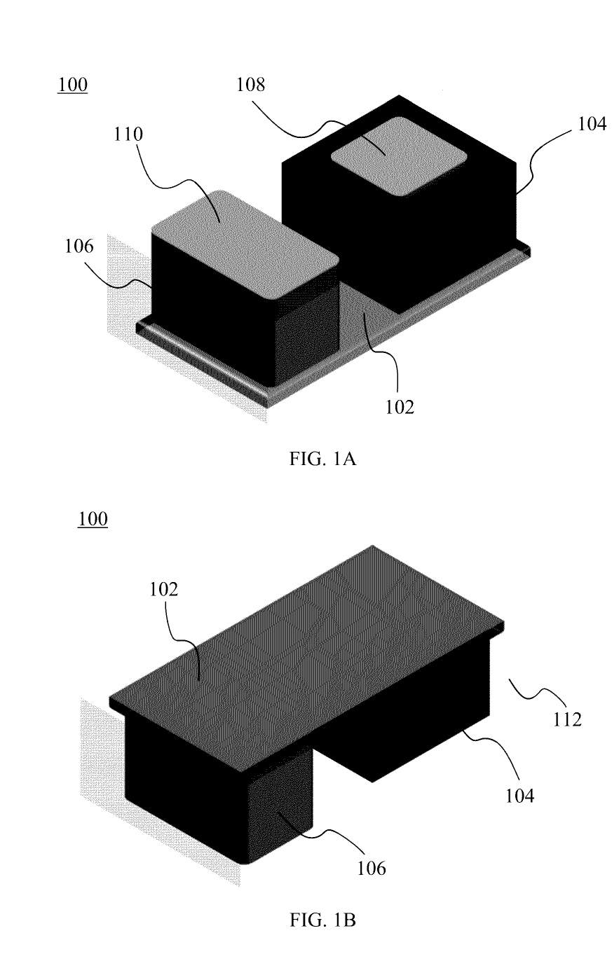

Referring to FIGS. 1A-1B, which are perspective views of the structure of an electronic device 100 in accordance with an embodiment of the present invention, the electronic device 100 includes a conductive layer 102, a device die 104, and a connecting member 106.

As can be seen from FIG. 1A, the device die 104 and the connecting member 106 are disposed on the conductive layer 102, and with a space therebetween. The device die 104 has a first connection point on one side thereof facing the conductive layer 102 (blocked by the device die 104, thus not visible in this illustration), for providing electrical connection between the device die 104 and the conductive layer 102. The device die 104 provides on another surface a second connection point 108. Similarly, the connecting member 106 has a third connection point (not shown) on one side thereof facing the conductive layer 102 for providing connection between the connecting member 106 and the connection layer 102. The connecting member 106 also has a fourth connection point 110 on the other surface thereof.

In an alternative embodiment, the second connection point 108 and the fourth connection point 110 are respectively applied with corresponding coatings to protect the connection points from being affected by the external environment such as oxidation.

It will be appreciated that through the second connection point 108 and the fourth connection point 110, the electronic device 100 provides external electrical connections. In an alternative embodiment, the first connection point and the second connection point 108 are located on opposite sides of the device die 104, and the third connection point and the fourth connection point 110 are also located on opposite sides of the connecting member 106.

In one embodiment, the second connection point 108 and the fourth connection point 110 may be set in the same plane, such that subsequently when the electronic device 100 is mounted to for example a Printed Circuit Board (PCB), it is possible to easily form an external connection.

Referring to FIG. 1B, after the device die 104 and the connecting member 106 are assembled on the conductive layer 102, molding material 112 is used to encapsulate the assembly to form the electronic device 100. In an alternative embodiment, the electronic device 100 includes on a side of the conductive layer 102 opposite to that to which the device die 104 and the connecting member 106 are connected a non-conductive layer (not shown), thereby providing protection for the connection layer 102.

According to an alternative embodiment, the connecting member 106 is made of conductive material, for example copper (Cu). Accordingly, the first connection point on the device die 104 is electrically guided to the fourth connection point 110 via the conductive connection layer 102 and the connecting member 106.

In an embodiment of the present invention, the conductive layer 102 is formed by coating conductive material on a heat-removable film. Accordingly, during the manufacturing of the electronic device, the use of a lead frame or the step of wire bonding is not performed. The electronic device 100 can be manufactured by applying the conductive layer 102, mounting the device die 104, and mounting the connecting member 106. The manufacturing cost and the assembly time of the electronic device 100 are saved by not using a lead frame.

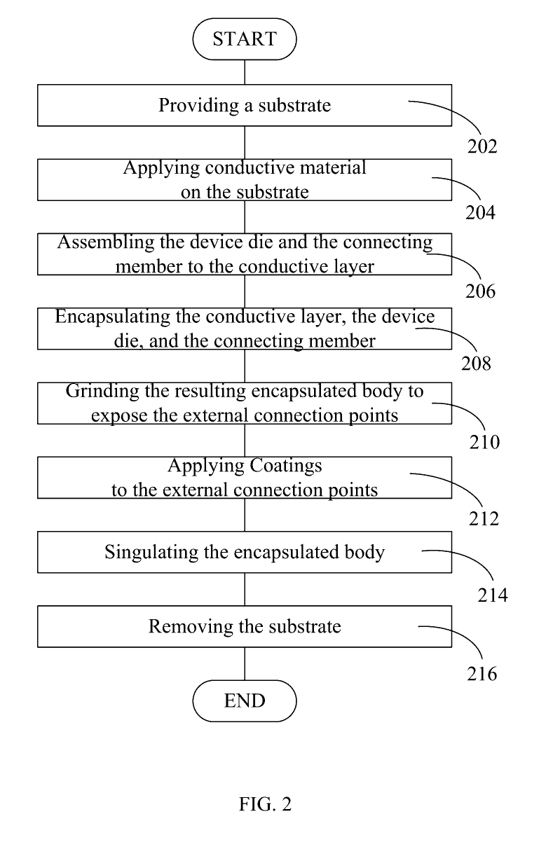

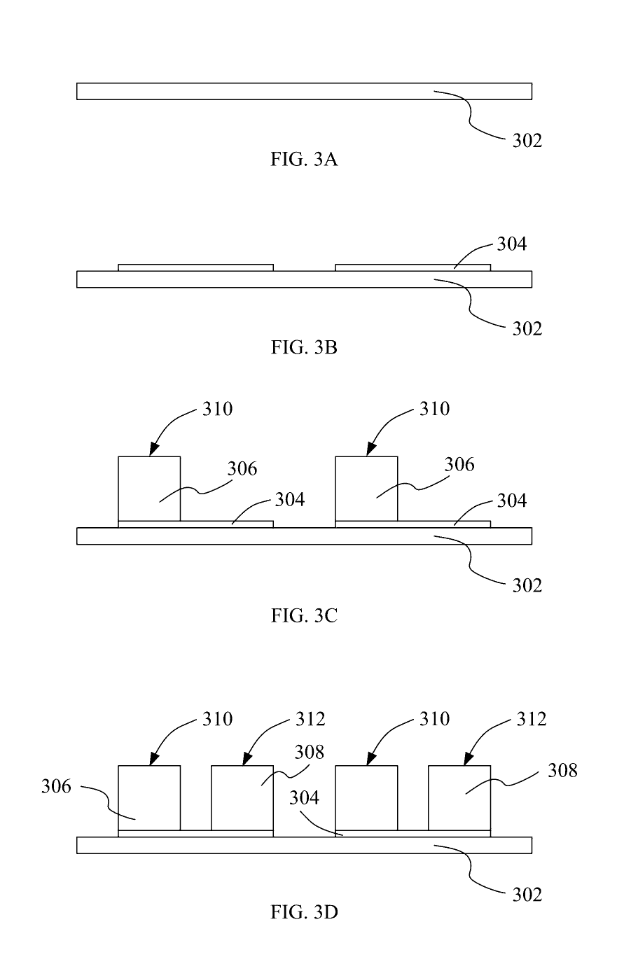

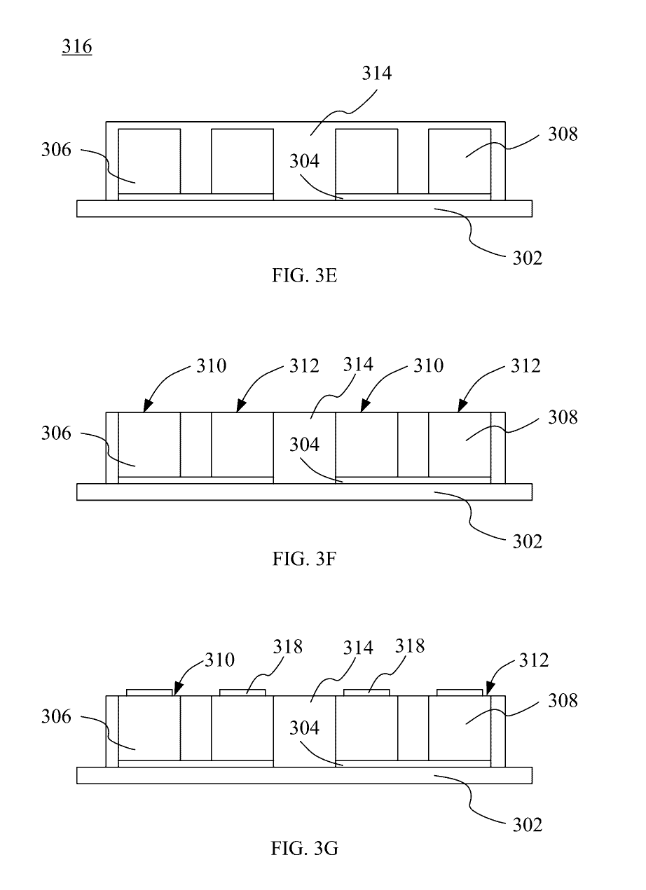

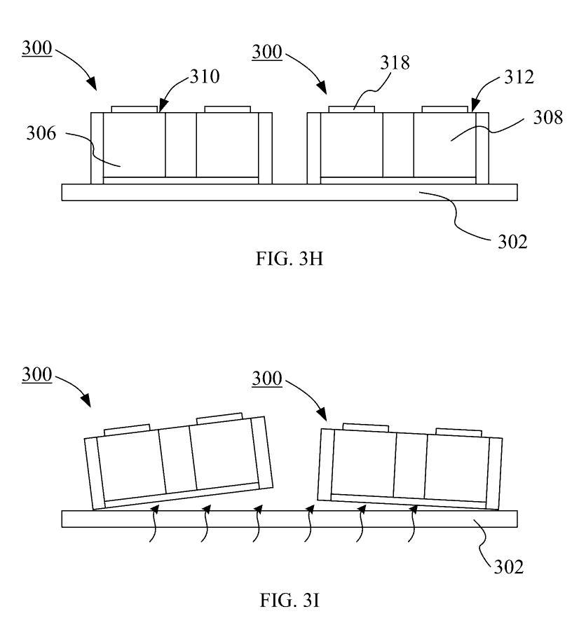

Shown in FIG. 2 is a flow chart of a method for manufacturing an electronic device according to an embodiment of the present invention. With reference to FIGS. 3A to 3I, cross-sectional side views of the structures formed in each step in a method for manufacturing an electronic device are shown.

Step 202 is providing a substrate 302. As shown in FIG. 3A, the substrate 302 may comprise a thermally removable film, for example, a heat-removable film of 200° C.

In step 204, a conductive material is applied on the substrate 302 to form a conductive layer 304.

More specifically, as shown in FIG. 3B, a conductive glue is coated on the substrate 302 through techniques like dispense or screen printing. In the coating process, the conductive adhesive 304 is applied at required mounting positions of the device die and the connecting member, and required position for electrical connection, but not on other unwanted locations.

Step 206 is attaching a device die and a connecting member to the conductive layer 304.

Specifically, as shown in FIGS. 3C and 3D, the device die 306 and the connecting member 308 are attached on the conductive layer 304. The device die 306 and the connecting member 308 may be mounted at corresponding positions of the conductive layer 304 that are coated. The device die 306 and the connecting member 308 preferably are spaced from each other. The device die 306 and the connecting member 308 are provided with internal connection points on the sides thereof facing the conductive layer 304 for providing electrical connection to the conductive layer 304. The device die 306 and the connecting member 308 are provided with external connection points 310, 312 on the opposite sides thereof for providing external connections. It will be understood by those of skill in the art that the external connection points 310, 312 provide the electronic device with final external electrical connections.

In one alternative embodiment, the internal connection points of the device die 306 and/or the connecting member 308 and the external connection points 310, 312 are located on opposite sides of their respective surfaces. However, in other alternative embodiments, the internal connection points and the external connection points may be configured to have other relative positional relationships.

In one alternative embodiment, when the device die 306 and the connecting member 308 are mounted on the conductive layer 304, the external connection points 310, 312 are configured to be located on the same plane. However, in other alternative embodiments, the external connection point 310 of the device die 306 and the external connection point 312 of the connecting member 308 can be arranged in different relative positions.

Step 208 is encapsulating the conductive layer, the device die, and the connecting member.

With reference to FIG. 3E, after attaching the device die 306 and the connecting member 308 to the conductive layer 304, the assembled body is encapsulated by molding material 314 to form a body 316. Typically, liquid molding material 314 flows into a mold and surrounds the assembly to form an encapsulated body 316. In an exemplary embodiment, since in step 202 a 200° C. heat-removable film is used as the substrate 302, the molding material 314 used when in its liquid state should not have a temperature exceeding 200° C. in order to avoid removal of the thermal removable film. For example, a 120° C. liquid molding process or a 170° C. transfer molding process can be used to form the encapsulated body 316.

Step 210 is grinding the resulting encapsulated body 316 to expose the external connection points 310, 312.

With reference to FIG. 3F, in the resulting encapsulated body 316, the external connection points 310, 312 of the device die 306 and the connecting member 308 may be covered by the molding material 314. In this case, it is necessary to use certain process(es) to expose the external connection points 310, 312 to be able to provide external connectivity for the electronic device. In this embodiment, the encapsulated body 316 is grinded to remove the covering molding material 314 so that the external connection points 310, 312 are exposed. It will be appreciated, if the molding material 314 does not cover the external connection points 310, 312, that the present invention does not require the removal of such covering molding material 314 to expose the external connection points 310, 312. Further, removal of the molding material 314 may also be accomplished in other ways so should not be limited grinding.

In step 212, a coating is applied to the external connection points 310, 312.

As shown in FIG. 3G, in an alternative embodiment, the connecting member 308 is made of copper (Cu), the external connection points 310, 312 may be made of tin (Sn), copper (Cu) and other materials. In order to protect the external connection points 310 and 312 in subsequent processing, such as from environmental impacts like corrosion or oxidation, external connection points 310 and 312 may be plated with a suitable protective layer 318.

It should be noted that the external connection point 310 of the device die 306 may already be covered with an appropriate protective layer during wafer fabrication, which is before the manufacturing of the electronic device of the present invention, so as to protect the external connection point 310 from being impacted by the aforementioned steps of manufacturing process. Accordingly, the present invention does not necessarily require the process of step 212 to apply the coating. A similar situation may be with the external connection point 312 of the connecting member 308. Further, in FIG. 3G, the protective layer 318 is not drawn to scale in order to show clearly the layer 318.

Step 214 comprises singulating the encapsulated body.

As shown in FIG. 3H, when more than one electronic device is formed simultaneously (each electronic device includes a predetermined amount of each of the conductive layer 304, the device die 306 and connecting member 308), after molding and possible grinding, the encapsulated body 316 may include multiple corresponding individual devices. Through processes like sawing, laser, etc., the encapsulated body 316 can be divided along a predetermined dicing lane into corresponding electronic devices 300. In the current exemplary embodiment, singulation by sawing, laser or the like stops at the junction of the connecting member 304 and the substrate 302. It will be appreciated that in other embodiments, the encapsulated body 316 can be fully cut together with the substrate 302.

In step 216, the substrate is removed.

Please refer to FIG. 31, if the substrate 302 employs the 200° C. heat-release film as indicated in the described embodiment, by heating the heat-removable film, the electronic devices 300 are separated from the film.

In another embodiment, a method of manufacturing the electronic device may further include, on a back surface of the electronic device 300 obtained by the removal at step 216, i.e. the surface of the connecting member 304 opposite to that the device die 306 and the connecting member 308 is attached, configuring a corresponding protective layer (not shown), which may be arranged in various ways.

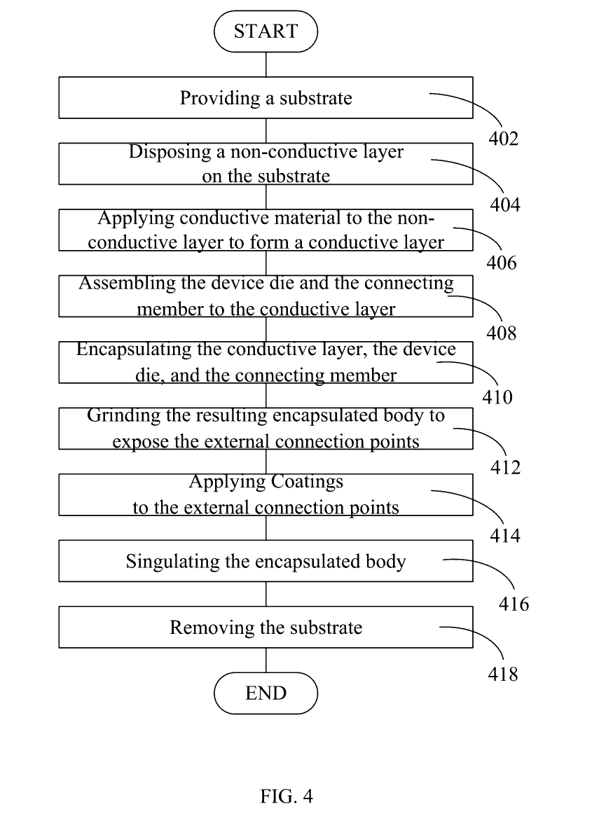

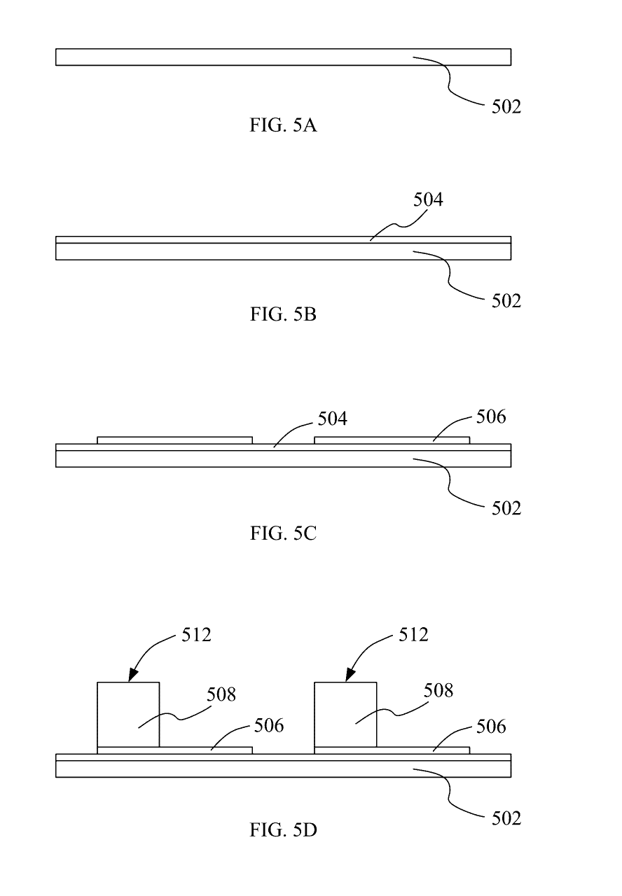

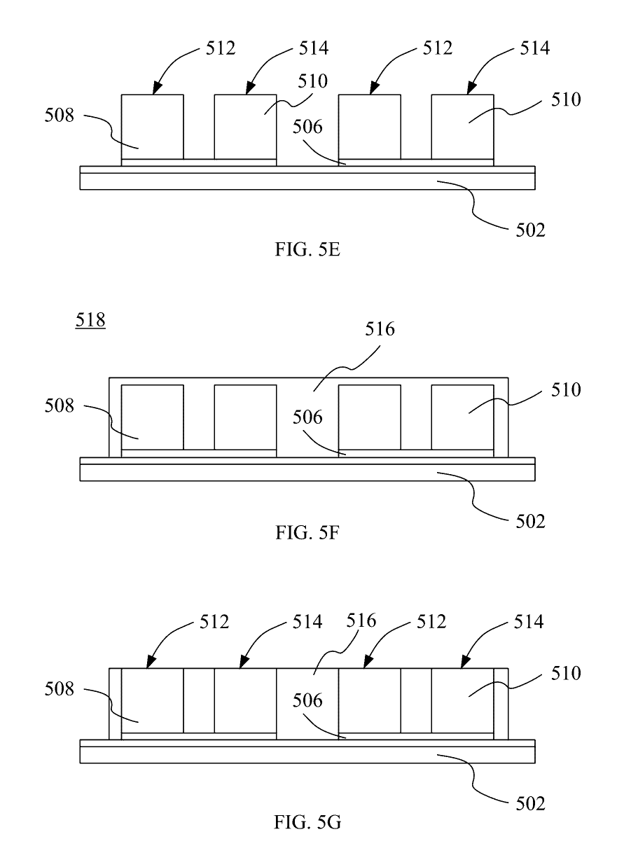

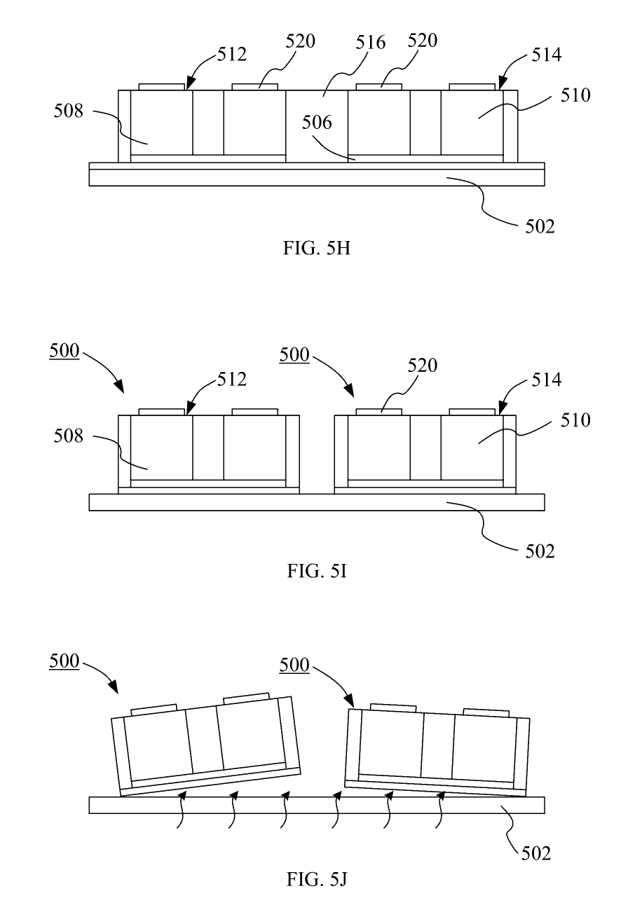

Referring to FIG. 4, a flow chart of a manufacturing method for an electronic device according to another embodiment of the present invention is shown. Much of the process of this embodiment is similar to the process shown in FIG. 2, so the similarities will not be described, while the steps with substantial differences will be explained. In addition, FIGS. 5A to 5J show cross-sectional side views of the resulting structures of the steps of FIG. 4, and hereby it will only be described those with substantial differences from those shown in FIGS. 3A-3I.

In the embodiment shown in FIG. 4, after a step 402 of providing a substrate, in step 404, a non-conductive layer is disposed on the substrate.

Specifically, as shown in FIG. 5B, a non-conductive layer 504 may be disposed on a 200° C. heat-removable film substrate 502. In an alternative embodiment, the non-conductive layer 504 may be a non-conductive Die Attach Film (DAF).

After step 404, in step 406, conductive material is applied to the non-conductive layer to form a conductive layer. Specifically, as shown in FIG. 5C, being similar to step 204 of FIG. 2, conductive material is coated on the non-conductive layer 504 to form a conductive layer 506. After forming the conductive layer 506, the non-conductive layer 504 is located between the conductive layer 506 and the substrate 502.

In the current embodiment, the subsequent steps 408-418 are similar to steps 206 to 216 in FIG. 2 and will not be described again. The resulting structure of each step is shown in FIGS. 5D-5J, which have similar characteristics as the structures shown in FIGS. 3C through 31, such as a device die 508 and its external connection point 512, a connecting member 510 and its external connection point 514, a molding material 516, an encapsulated body 518, a coating 520, and an electronic device 500.

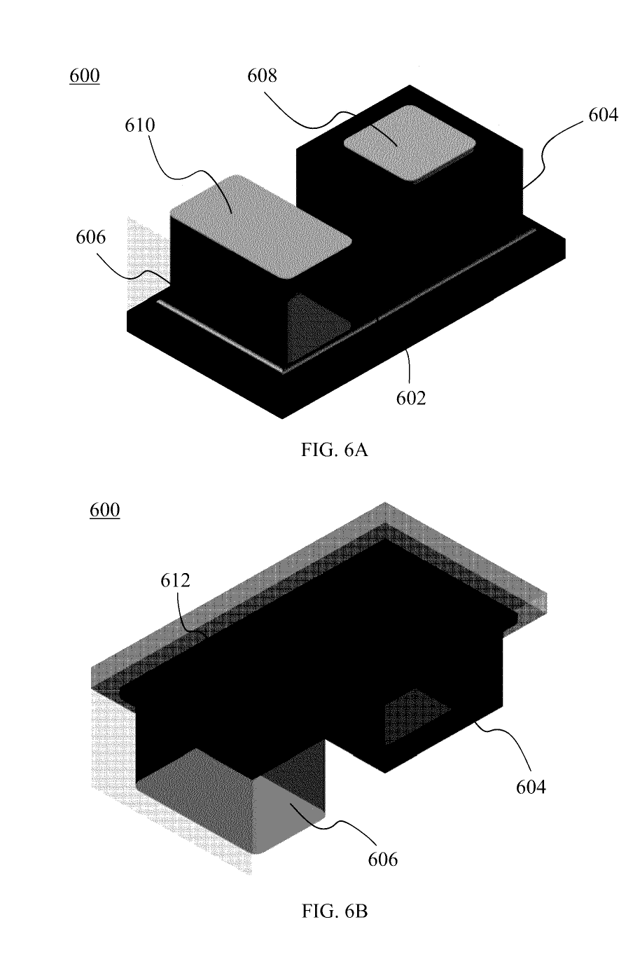

Referring FIG. 6A, which is a perspective view of the electronic device 600 formed in the embodiment of FIGS. 4 and 5, it can be seen that the electronic device 600 includes a conductive layer 602, a device die 604 and its external connection point 608, a connecting member 606 and its external connection point 610, and so on. Further, as shown in FIG. 6B, the electronic device 600 further includes on its back surface a non-conductive layer 612, so that the conductive layer 602 is located between the non-conductive layer 612 and the connecting member 606, and between the device die 604 and the connecting member 606. By including the non-conductive layer 612, the conductive layer 602 also is protected in the operation of the electronic device 600, so that the electronic device 600 may be more reliable.

In various embodiments of the present invention, the conductive layer 304, 506 are formed by coating conductive material on the heat-removable film. Accordingly, during the manufacturing of the electronic devices 300 and 500, the use of the lead frame or the step of wire bonding is not involved. The electronic device can be directly manufactured through applying the conductive layer, mounting the device die, and mounting the connecting member. The manufacturing cost and the processing time of the electronic device can be saved by saving the manufacture and use process of the lead frame.

The use of the terms “a” and “an” and “the” and similar referents in the context of describing the subject matter (particularly in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. Furthermore, the foregoing description is for the purpose of illustration only, and not for the purpose of limitation, as the scope of protection sought is defined by the claims as set forth hereinafter together with any equivalents thereof entitled to. The use of any and all examples, or exemplary language (e.g., “such as”) provided herein, is intended merely to better illustrate the subject matter and does not pose a limitation on the scope of the subject matter unless otherwise claimed. The use of the term “based on” and other like phrases indicating a condition for bringing about a result, both in the claims and in the written description, is not intended to foreclose any other conditions that bring about that result. No language in the specification should be construed as indicating any non-claimed element as essential to the practice of the invention as claimed.

Preferred embodiments are described herein, including the best mode known to the inventor for carrying out the claimed subject matter. Of course, variations of those preferred embodiments will become apparent to those of ordinary skill in the art upon reading the foregoing description. The inventor expects skilled artisans to employ such variations as appropriate, and the inventor intends for the claimed subject matter to be practiced otherwise than as specifically described herein. Accordingly, this claimed subject matter includes all modifications and equivalents of the subject matter recited in the claims appended hereto as permitted by applicable law. Moreover, any combination of the above-described elements in all possible variations thereof is encompassed unless otherwise indicated herein or otherwise clearly contradicted by context.

1. An electronic device, comprising:
a conductive layer;
a device die; and
a connecting member,
wherein:
the conductive layer is formed by coating a conductive material on a substrate,
the device die and the connecting member are disposed on the conductive layer and spaced from each other,
the device die comprises a first connection point on a side thereof in contact with and electrically connected to the conductive layer, and a second connection point on another side thereof,
the connecting member comprises a third connection point on a side thereof electrically connected to and in contact with the conductive layer, and a fourth connection point on another side thereof, and
the second connection point and the fourth connection point are configured to provide external connections of the electronic device.

2. The electronic device according to claim 1, further comprising a coating applied on the second and fourth connection points.

3. The electronic device according to claim 1, wherein the substrate is a heat-removable film.

4. The electronic device according to claim 1, wherein the connecting member comprises copper.

5. The electronic device according to claim 1, further comprising a non-conductive layer on a side of the conductive layer opposite to the side on which the device die and the connecting member are disposed.

6. The electronic device according to claim 1, wherein the first connection point and the second connection point are located on opposite sides of the device die.

7. The electronic device according to claim 1, wherein the third connection point and the fourth connection point are located on opposite sides of the connecting member.

8. The electronic device according to claim 1, wherein the second and the fourth connection points are configured in the same plane.

9. A method for manufacturing an electronic device, comprising:
applying conductive material on a substrate to form a conductive layer;
arranging a device die and a connecting member on the conductive layer, wherein the device die and the connecting member are spaced from each other, and wherein the device die and the connecting member respectively have internal connection points on a side thereof contacting the conductive layer, and have external connection points on another side thereof different from the side contacting the conductive layer;
encapsulating the conductive layer, the device die, and the connecting member, and exposing the external connection points of the device die and the connecting member; and
removing the substrate.

10. The method according to claim 9, wherein prior to the step of applying conductive material on the substrate, the method further comprises:
disposing a non-conductive layer on the substrate, such that the non-conductive layer is located between the conductive layer and the substrate.

11. The method according to claim 9, wherein exposing the external connection points of the device die and the connecting member comprises:
grinding an encapsulated body obtained by encapsulating the conductive layer, the device die and the connecting member to expose the external connection points of the device die and the connecting member.

12. The method according to claim 9, wherein after the exposing the external connection points of the device die and the connecting member, the method further comprises:
coating the external connection points of the device die and the connecting member.

13. The method according to claim 9, wherein the external connection points of the device die and/or the connecting member are respectively located on opposite sides of the corresponding device die and/or connecting member.

14. The method according to claim 9, wherein arranging the device die and the connecting member on the conductive layer comprises:
configuring the external connection points of the device die and the connecting member to be in the same plane.

15. The method according to claim 9, wherein the substrate is a heat-removable film.
